(19) United States
(12) Patent Application Publication
(10) Pub. No.: US 2020/0051609 A1
(43) Pub. Date: Feb. 13, 2020

(54) MEMORY DEVICE AND IMAGE DISPLAY APPARATUS INCLUDING THE SAME

(71) Applicant: LG ELECTRONICS INC., Seoul (KR)

(72) Inventors: Hoshik KIM, Seoul (KR); Gwibeom HAN, Seoul (KR); Hoyeon HWANG, Seoul (KR)

(73) Assignee: LG ELECTRONICS INC., Seoul (KR)

(21) Appl. No.: 16/536,523

(22) Filed: Aug. 9, 2019

(30) Foreign Application Priority Data
Aug. 10, 2018 (KR) 10-2018-0093692

(51) Int. Cl. G11C 11/4076; G11C 11/406; G06F 12/14

(52) U.S. Cl. CPC G11C 11/4076; G06F 2212/25; G06F 12/14; G11C 11/40615

(57) ABSTRACT

A memory device including a memory; a clock generator including a dual phase locked loop (PLL) and outputting a clock signal of the memory; and a memory controller configured to perform dynamic frequency scaling for changing a frequency of the clock signal of the memory based on the dual PLL. Further, phase detection is performed before the dynamic frequency scaling is started, and change the frequency of the clock signal of the memory during blocking of access to the memory according to the performance of the dynamic frequency scaling.

### CROSS-REFERENCE TO RELATED APPLICATION

This application claims the priority benefit of Korean Patent Application No. 10-2018-0093692, filed on Aug. 10, 2018 in the Korean Intellectual Property Office, the disclosure of which is incorporated herein by reference.

### BACKGROUND OF THE INVENTION

### 1. Field of the Invention

The present invention relates to a memory device and an image display apparatus including the same, and more particularly, to a memory device capable of reducing a memory access blocking period when a frequency of clock signal of a memory is changed, and an image display apparatus including the same.

### 2. Description of the Related Art

An image display apparatus includes a function of providing an image that a user can watch. The user can watch various images through the image display apparatus. Particularly, the image display apparatus can execute various events such as an internet screen display, a game screen display, and the like.

In addition, when executing various events, the image display apparatus writes and reads data to a memory device. Further, a method of changing the operation frequency of the memory device according to the event has been researched.

For example, US Patent Application Publication No. US 2012/0327726 describes a method of changing a frequency of clock signal by using a single PLL. However, according to such a method, there is a disadvantage in that a time delay in a mode switching is considerable due to a time required for a phase adjustment. Particularly, when the frequency of clock signal of a memory is changed, there is a disadvantage in that a memory access blocking period is considerable.

### SUMMARY OF THE INVENTION

Therefore, the present invention has been made in view of the above problems, and it is an object of the present invention to provide a memory device capable of reducing a memory access blocking period when a frequency of clock signal of a memory is changed, and an image display apparatus including the same.

It is another object of the present invention to provide a memory device capable of changing to various frequencies when a frequency of clock signal of a memory is changed, and an image display apparatus including the same.

In accordance with an aspect of the present invention, the above and other objects can be accomplished by the provision of a memory device including a memory; a clock generator configured to have a dual phase locked loop (PLL) and output a clock signal of the memory; and a memory controller configured to control the memory, wherein dynamic frequency scaling for changing a frequency of clock signal of the memory is performed based on the dual PLL, wherein phase detection is performed before the dynamic frequency scaling is started, and the frequency of clock signal of the memory is changed during blocking of access to the memory according to the performance of the dynamic frequency scaling.

Further scope of applicability of the present invention will become apparent from the detailed description given hereinafter. However, the detailed description and specific examples, while indicating preferred embodiments of the invention, are given by illustration only, since various changes and modifications within the spirit and scope of the invention will become apparent to those skilled in the art from this detailed description.

### BRIEF DESCRIPTION OF THE DRAWINGS

The above and other objects, features and other advantages of the present invention will be more clearly understood from the following detailed description taken in conjunction with the accompanying drawings, in which:

FIG. 1 illustrates execution of game application in an image display apparatus according to an embodiment of the present invention;

FIG. 2 is an example of a block diagram of the image display apparatus of FIG. 1;

FIG. 3 illustrates an example of an internal block diagram of a memory device according to an embodiment of the present invention;

FIG. 4A to FIG. 4C are diagrams illustrating an operation of a conventional memory device;

FIG. 5 is a flowchart illustrating an operation method of a memory device according to an embodiment of the present invention;

FIG. 6 is a flowchart showing a method of operating a conventional memory device;

FIG. 7 is a flowchart illustrating an operation method of a memory device according to an embodiment of the present invention; and

FIGS. 8A to 11 are diagrams illustrating various examples of an operation method of a memory device of FIG. 7.

### DETAILED DESCRIPTION OF THE PREFERRED EMBODIMENTS

Reference will now be made in detail to the preferred embodiments of the present invention, examples of which are illustrated in the accompanying drawings. Wherever possible, the same reference numbers will be used throughout the drawings to refer to the same or like parts. As used herein, the suffixes “module” and “unit” are added or used interchangeably to facilitate preparation of this specification and are not intended to suggest distinct meanings or functions. Accordingly, the terms “module” and “unit” may be used interchangeably.

An image display apparatus described in this document may include a mobile phone, a smart phone, a notebook computer, a TV, a monitor, a digital broadcasting terminal, a personal digital assistants (PDA), a portable multimedia player (PMP), a digital camera, a navigation device, a tablet computer, an e-book terminal, a wearable device such as a smart watch, and the like.

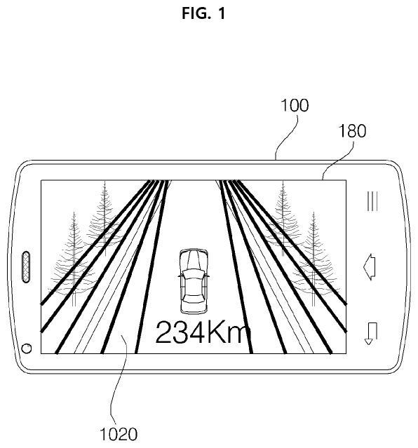

FIG. 1 illustrates execution of game application in an image display apparatus according to an embodiment of the present invention. As shown, the image display apparatus 100 of FIG. 1 can display a game image on a display 180 by executing a game application.

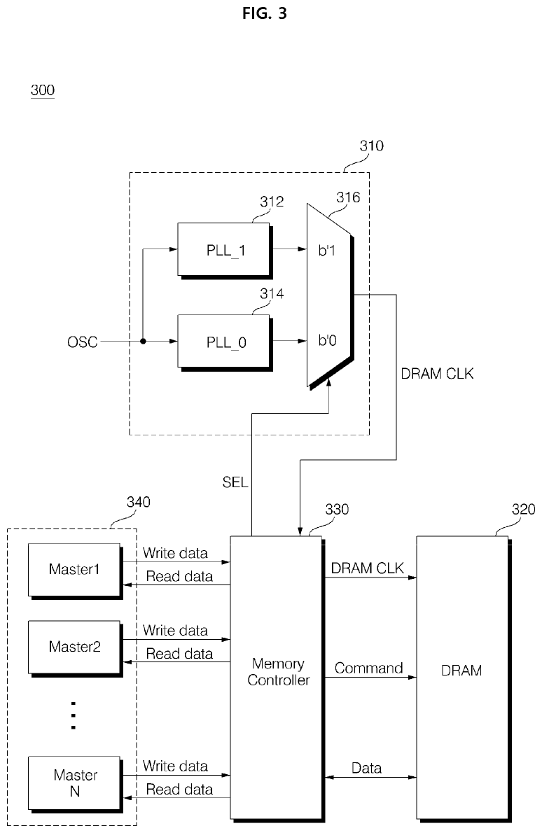

Thus, the image display apparatus 100 generates a graphic image frame by using graphic data, and displays the graphic image frame on the display 180, when executing the game application. Further, the graphic data, and the like can be written into or read from a memory device 300 (FIG. 3).

In particular, when executing the game application, traffic for a memory in the memory device (300 in FIG. 3) may increase. Accordingly, a scheme for varying a frequency of clock signal of the memory according to the memory traffic is required. According to this scheme, when the memory traffic increases, the frequency of clock signal of the memory can be increased, and when the memory traffic decreases, the frequency of clock signal of the memory can be decreased. This is referred to as dynamic frequency scaling. In addition, the is an advantage in that unnecessary power consumption can be reduced according to the dynamic frequency scaling.

One embodiment of the present invention describes a method for reducing a memory access blocking period when the frequency of clock signal of the memory is changed when a frequency of a clock signal of the memory is changed. Further, one embodiment of the present invention describes a method capable of changing into various frequencies when a frequency of clock signal of a memory is changed. This will be described later with reference to FIG. 3.

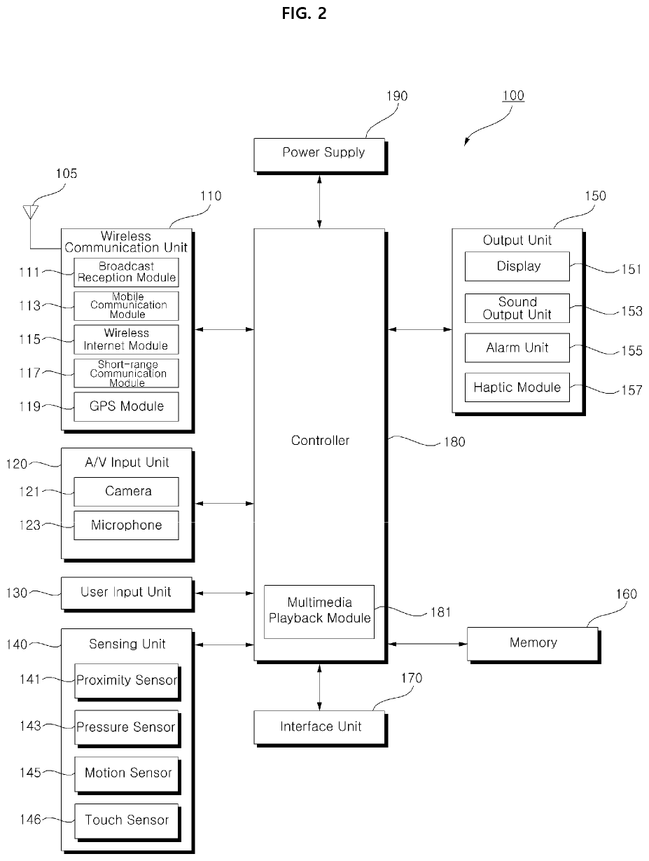

Next, FIG. 2 is a block diagram of the mobile terminal 100 of FIG. 1. Referring to FIG. 2, the mobile terminal 100 may include a wireless communication unit 110, an audio/video (A/V) input unit 120, a user input unit 130, a sensing unit 140, an output unit 150, a memory 160, an interface unit 170, a controller 180, and a power supply 190. When these components are implemented in an actual application, two or more components may be combined into one component or one component may be subdivided into two or more components, as needed.

The wireless communication unit 110 may include a broadcast reception module 111, a mobile communication module 113, a wireless Internet module 115, a short-range communication module 117, and a GPS module 119. The broadcast reception module 111 may receive at least one of a broadcast signal and broadcast-related information from an external broadcast management server on a broadcast channel. The broadcast signal and/or the broadcast-related information received through the broadcast reception module 111 may be stored in the memory 160.

The mobile communication module 113 may transmit and receive a wireless signal to and from at least one of a base station, an external terminal, or a server over a mobile communication network. Here, the wireless signal may include a voice call signal, a video call signal, or various types of data according to transmission/reception of a text/multimedia message.

The wireless Internet module 115 refers to a module for wireless Internet access. The wireless Internet module 115 may be installed inside or outside the mobile terminal 100. The short-range communication module 117 refers to a module for short-range communication. Bluetooth, Radio Frequency Identification (RFID), Infrared Data Association (IrDA), Ultra Wideband (UWB), ZigBee, and Near Field Communication (NFC), or the like may be used as the short-range communication technology. The Global Positioning System (GPS) module 119 receives position information from a plurality of GPS satellites.

The audio/video (A/V) input unit 120 is configured to receive input of an audio signal or a video signal, and may include a camera 121 and a microphone 123. The camera 121 may process an image frame such as a still image or a moving image acquired by the image sensor in a video call mode or a photographing mode. Then, the processed image frame can be displayed on the display 151.

The image frame processed by the camera 121 may be stored in the memory 160 or transmitted to the outside through the wireless communication unit 110. The camera 121 may also include two or more cameras according to the configuration of the terminal.

Further, the microphone 123 can receive an external audio signal such as, for example, a call mode, a recording mode, or a speech recognition mode, in a display off mode, and may process the signal into electrical voice data. A plurality of microphones 123 may be arranged at different positions. The audio signal received through each microphone may be subjected to audio signal processing in the controller 180 or the like.

In addition, the user input unit 130 generates key input data that the user inputs to control the operation of the terminal. The user input unit 130 may include a key pad, a dome switch, and a touch pad (resistive touch pad/capacitive touch pad) capable of receiving commands or information according to the pressing or touch operation performed by the user. Particularly, when the touch pad forms a layered structure with the display 151, which will be described later, the structure is called a touchscreen.

Further, the sensing unit 140 can sense the current state of the mobile terminal 100, such as the open/closed position of the mobile terminal 100, the location of the mobile terminal 100, and presence of a user touch, and generate a sensing signal for controlling the operation of the mobile terminal 100. As shown, the sensor unit 140 may include a proximity sensor 141, a pressure sensor 143, a motion sensor 145, and a touch sensor 146.

The proximity sensor 141 can detect an object approaching the mobile terminal 100 or presence/absence of an object around the mobile terminal 100 without mechanical contact. In particular, the proximity sensor 141 can detect a nearby object using change in the alternating magnetic field or change in the static magnetic field, or a change rate of the capacitance. The pressure sensor 143 can also detect information indicating whether pressure is applied to the mobile terminal 100, the magnitude of the pressure, and the like.

The motion sensor 145 can detect the position or movement of the mobile terminal 100 using an acceleration sensor, a gyro sensor, or the like. Further, the touch sensor 146 can sense a touch input by user's finger or a touch input by a specific stylus. For example, when the touchscreen panel is disposed on the display 151, the touchscreen panel may include the touch sensor 146 to sense the position information and intensity information about the touch input. The sensing signal sensed by the touch sensor 146 can also be transmitted to the controller 180.

In addition, the output unit 150 is provided to output an audio signal, a video signal, or an alarm signal. As shown, the output unit 150 may include a display 151, a sound output unit 153, an alarm unit 155, and a haptic module 157.

The display 151 outputs information processed by the mobile terminal 100 by displaying the information. For example, when the mobile terminal 100 is in the call mode, a user interface (UI) or graphical user interface (GUI) related to the call is displayed. When the mobile terminal 100 is in the video call mode or the photographing mode, the display 151 may display the captured or received images individually or simultaneously, and display the UI and the GUI. As described above, when the display 151 and the touch pad form a layered structure to constitute a touchscreen, the display 151 can be used not only as an output device, but also as an input device for inputting information according to a user touch.

The sound output unit 153 can output audio data received from the wireless communication unit 110 or stored in the memory 160 in a call signal reception mode, a call mode, a recording mode, a speech recognition mode, or a broadcast reception mode. The sound output unit 153 outputs audio signals related to functions performed by the mobile terminal 100 such as, for example, call signal reception tones and message reception tones. The sound output unit 153 may also include a speaker and a buzzer.

Further, the alarm unit 155 outputs a signal for announcing occurrence of an event in the mobile terminal 100. The alarm unit 155 outputs a signal for announcing occurrence of an event in a form other than an audio signal or a video signal. For example, the alarm unit 155 may output a signal in the form of vibration.

The haptic module 157 generates various tactile effects that the user can feel. A typical example of the haptic effects generated by the haptic module 157 is vibration. When the haptic module 157 generates vibration as a haptic effect, the intensity and pattern of the vibration generated by the haptic module 157 are changeable, and different types of vibration may be synthesized and output or sequentially output.

In addition, the memory 160 can store a program for processing and control in the controller 180 and function to temporarily store input or output data (e.g., a phone book, messages, still images, moving images, etc.).

Also, the interface unit 170 serves as an interface with all external devices connected to the mobile terminal 100. In more detail, the interface unit 170 can receive data or power from an external device, transmit the received data to each component in the mobile terminal 100 and allow data in the mobile terminal 100 to be transmitted to an external device.

Further, the processor or controller 180 typically controls the operation of the respective parts mentioned above to control the overall operation of the mobile terminal 100. For example, the controller 180 can perform related control and processing for voice calls, data communication, video calls, and the like. The controller 180 may include a multimedia playback module 181 for multimedia playback. The multimedia playback module 181 may be configured in hardware in the controller 180 or in software separately from the controller 180. The controller 180 may include an application processor to execute an application. Alternatively, an application processor may be provided separately from the controller 180. Under control of the controller 180, the power supply 190 may receive power from an external power source and an internal power source, and supply power required for operation of the respective components.

Next, FIG. 3 illustrates an example of an internal block diagram of a memory device 300 according to an embodiment of the present invention. As shown, the memory device 300 according to an embodiment of the present invention may include a memory 320, a clock generator 310 having a dual phase locked loop (PLL) and outputting a clock signal of the memory 320, and a memory controller 330 for controlling the memory 320. In addition, the memory device 300 may further include a processor 340 for exchanging read data or write data with the memory controller 330.

The memory 320 may be, for example, a dynamic RAM as a volatile memory. In addition, the clock generator 310 may include a first phase locked loop (PLL) and a second phase locked loop (PLL) which operate based on an oscillation signal (OSC).

The first PLL 312 and the second PLL 314 can operate alternately for dynamic frequency scaling. Specifically, in a first period, when the first PLL 312 operates to output a first clock signal, the memory 320 can operate in a first frequency based on the first clock signal. In a second period subsequent to the first period, when the second PLL 314 operates to output a second clock signal, the memory 320 can operate in a second frequency based on the second clock signal. Accordingly, the frequency of clock signal of the memory 320 can be changed continuously.

Further, the clock generator 310 may further include a multiplexer 316 for selecting any one of the first PLL 312 and the second PLL 314. Particularly, the multiplexer 316 can select any one of the first PLL 312 and the second PLL 314 based on a selection signal SEL from the memory controller 330. Accordingly, the clock generator 310 can output a clock signal (DRAM CLK) from the selected one of the first PLL 312 and the second PLL 314.

In addition, the clock signal (DRAM CLK) output from the clock generator 310 may be input to the memory controller 330. The memory controller 330 also controls the memory 320. In more detail, the memory controller 330 can output a clock signal (DRAM CLK) and a command signal (Command) to the memory 320, and exchange data with the memory 320.

For example, the memory controller 330 can perform the dynamic frequency scaling according to the traffic of the memory 320. Specifically, the memory controller 330 can control the frequency of clock signal of the memory 320 to increase as the traffic of the memory 320 increases. In particular, the memory controller 330 can output a selection signal (SEL) for increasing the frequency of clock signal.

In addition, the memory controller 330 can control the access to the memory 320 to be blocked, when changing the frequency of clock signal of the memory 320. The memory controller 330 can also perform dynamic frequency scaling for changing the frequency of clock signal of the memory 320 based on the dual PLL, perform phase detection before starting the dynamic frequency scaling, and change the frequency of clock signal of the memory 320 to during the blocking of the access to the memory 320 according to the performance of dynamic frequency scaling. Accordingly, the memory 320 access blocking time can be reduced when the frequency of clock signal of the memory 320 is changed.

Further, the memory controller 330 can set the parameter of the second PLL 314 while the memory 320 is operating, based on the first clock signal from the first PLL 312 of the dual PLL, and perform the dynamic frequency scaling after the phase detection is performed in the clock generator 310. Accordingly, the memory 320 access blocking time can be reduced when the frequency of clock signal of the memory 320 is changed.

In addition, after the parameter of the second PLL 314 is set, the memory controller 330 can set a parameter of the memory controller 330, and perform the dynamic frequency scaling. Accordingly, the memory 320 access blocking time can be reduced when the frequency of clock signal of the memory 320 is changed.

When changing the frequency of clock signal of the memory 320, the memory controller 330 can change the frequency of clock signal of the memory 320, based on the second clock signal according to the set parameter of the second PLL 314. Accordingly, the memory 320 access blocking time can be reduced when the frequency of clock signal of the memory 320 is changed.

In addition, the memory controller 330 performs dynamic frequency scaling according to the traffic of the memory 320. Particularly, as the traffic of the memory 320 increases, the frequency of clock signal of the memory 320 can be controlled to increase. Accordingly, the power consumption of the memory 320 can be varied according to the traffic of the memory 320.

Further, the memory controller 330 can control the maximum frequency of clock signal of the memory 320 not to be an integer multiple of the minimum frequency. Accordingly, the changes to various frequencies can be achieved, when the frequency of clock signal of the memory 320 is changed.

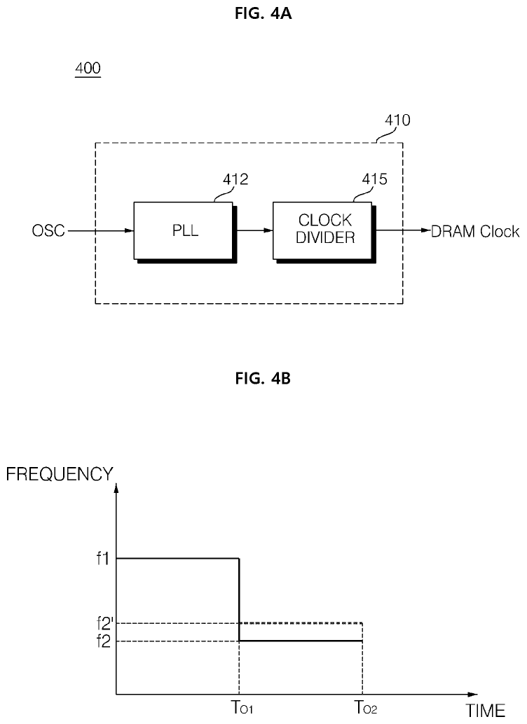

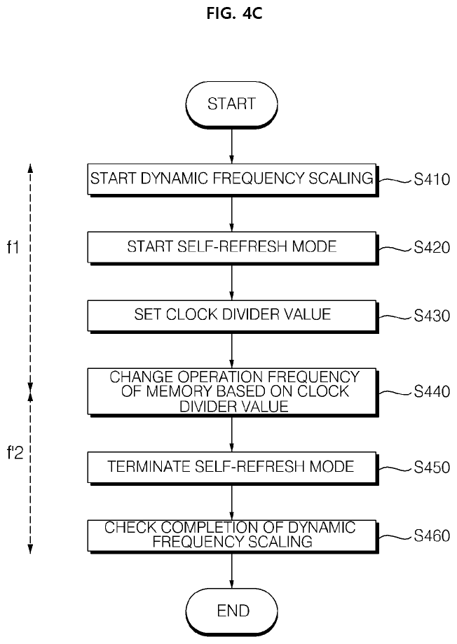

Next, FIGS. 4A and 4B are diagrams illustrating an operation of a conventional memory device. Firstly, FIG. 4A is a diagram illustrating a clock generator 410 inside a conventional memory device 400. Referring to the drawing, the clock generator 410 in the conventional memory device 400 may include a single PLL 412 and a clock divider 415 for performing clock division.

For example, according to the structure of FIG. 4A, when the single PLL 412 outputs a clock signal having the maximum frequency, the clock divider 415 divides the clock signal and outputs a clock signal having a frequency of 1/n of the maximum frequency. Here, n is an integer. That is, according to the structure of FIG. 4A, the maximum frequency may be an integer multiple of the frequency of clock signal of the memory.

Next, FIG. 4B illustrates when the clock frequency of the memory is lowered to a second frequency f2, at the time point Tol, from a first frequency f1. Further, the first frequency f1 may be the maximum frequency, and the first frequency f1 and the second frequency f2 may not form a relationship of integer multiple.

In this instance, according to the structure of FIG. 4A, the conventional memory device 400 is difficult to implement various frequencies of clock signal, and thus does not use a necessary frequency of clock signal, but uses a third frequency f2 which is closest to the second frequency f2. Accordingly, unnecessary power consumption occurs. Further, the third frequency f2 and the first frequency f1 may correspond to the relationship of integer multiple.

Next, FIG. 4C is a flowchart showing an operation method of the memory device of FIG. 4A. Referring to the drawing, the memory device 400 of FIG. 4A starts dynamic frequency scaling for varying a frequency in a state in which the frequency of clock signal is the first frequency f1 (S410). Next, the memory in the memory device 400 starts a self-refresh mode (S420).

the memory device 400 then generates a clock divider value for frequency change (S430). For example, the clock divider 415 can set the clock divider value to be divided, at the maximum frequency. Next, the memory device 400 changes the frequency of clock signal of the memory, based on the clock divider value. Then, the operation frequency of the memory is changed, based on the frequency of clock signal of the memory (S440).

For example, the operation frequency can be changed to the third frequency f2 of FIG. 4B rather than the second frequency f2. Further, the third frequency f2 and the first frequency f1 may correspond to the relationship of integer multiple. For example, the first frequency f1 may be 1866 MHz, the second frequency f2 may be 800 MHz, and the third frequency f2 may be 933 MHz.

Next, the memory device 400 can terminate the self-refresh mode (S450). The memory device 400 then checks completion of dynamic frequency scaling (S460), and the dynamic frequency scaling is completed. From step 440 (S440) to step 460 (S460), the memory operates at the changed third frequency f2.

In addition, according to FIG. 4C, it is difficult to implement various frequencies of a clock signal, because only 1/n of the maximum frequency is available for the changeable frequency. In particular, since the third frequency f2 of 933 MHz is used instead of the second frequency f2 of 800 MHz, unnecessary power consumption occurs. The present invention provides a method of using a dual PLL, as shown in FIG. 3, to implement various frequencies of clock signal.

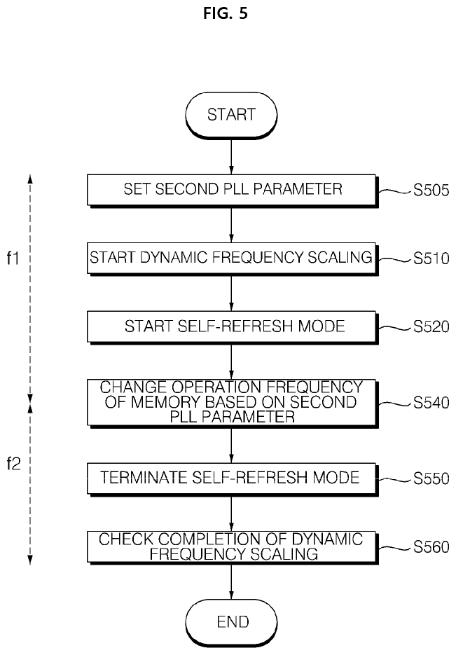

Next, FIG. 5 is a flowchart illustrating an operation method of a memory device according to an embodiment of the present invention. Referring to the drawing, the memory device 300 of FIG. 3 sets the second PLL 314 according to the first clock signal from the first PLL 312 of the dual PLL, in a state in which the dynamic frequency of the memory 320 is the first frequency f1 (S505).

Next, the memory device 300 of FIG. 3 starts the dynamic frequency scaling for varying a frequency (S510), and the memory 320 in the memory device 300 can start the self-refresh mode (S520). Then, the memory device 300 can change the frequency of clock signal of the memory 320 based on the second clock signal output from the second PLL 314, based on the set parameter of the second PLL 314. The operation frequency of the memory 320 is then changed based on the frequency of clock signal of the memory 320 (S540).

For example, the operation frequency can be changed to the second frequency f2 of FIG. 4B. Further, the second frequency f2 and the first frequency f1 may not be integer multiple. For example, the first frequency f1 may be 1866 MHz and the second frequency f2 may be 800 MHz. Next, the memory device 300 terminates the self-refresh mode (S550), and the memory device 300 checks the completion of dynamic frequency scaling (S560). Then, the dynamic frequency scaling is completed.

From step S540 to step S560, the memory operates at the changed second frequency f2. According to this, the second frequency f2 and the first frequency f1 are not integer multiple. Further, the memory device 300 of FIG. 3 can operate the memory 320 at various frequencies, which are not integer multiple as well as integer multiple, by using a dual PLL. In particular, the memory 320 can be operated at an operation frequency suitable for the traffic of the memory 320. Accordingly, unnecessary power consumption can be reduced.

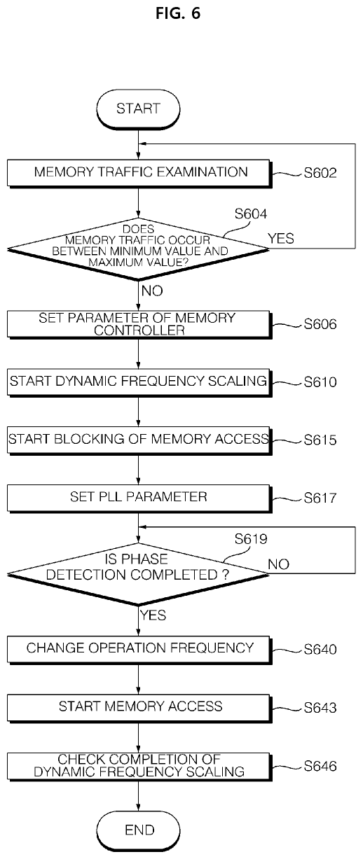

Next, FIG. 6 is a flowchart showing a method of operating a conventional memory device. Referring to the drawing, in the memory device 400 of FIG. 4A having a single PLL, memory traffic examination is performed (S602). If the examined memory traffic is in a normal range between a minimum value and a maximum value, the parameter of the memory controller is set (S606). Then, dynamic frequency scaling is started (S610). Next, after the dynamic frequency scaling, the blocking of memory access is started (S615), and parameter of the single PLL 412 is set (S617).

Then, it is determined whether phase detection in the single PLL 412 is completed (S619). If so, the frequency of clock signal from the single PLL 412 is varied, and the operation frequency of the memory is changed based on the varied frequency of clock signal (S640). After changing the operation frequency of the memory, the memory access is restarted (S643), and the completion of dynamic frequency scaling is checked (S646).

In FIG. 6, according to the conventional memory device 400, the memory access is blocked from step S615 to step S643. In this instance, the phase detection completion determination step S619 takes approximately 5 to 10 μs, and the memory access blocking period (PBkx) from step S615 to step S643 takes approximately 6 to 12 μs.

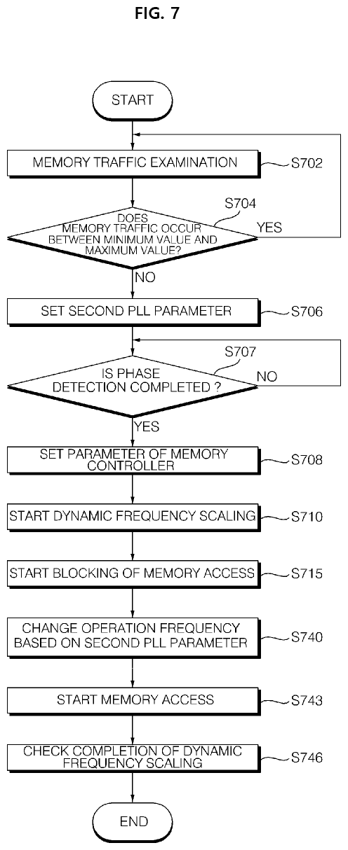

As described above, according to the conventional memory device 400, when the dynamic frequency is changed, there is a disadvantage in that the memory access blocking period (PBkx) becomes long so that the operation of the image display apparatus cannot be performed properly. Therefore, the present invention provides a method for reducing the memory access blocking time, when the dynamic frequency is changed. This will be described with reference to FIG. 7 and the following drawings.

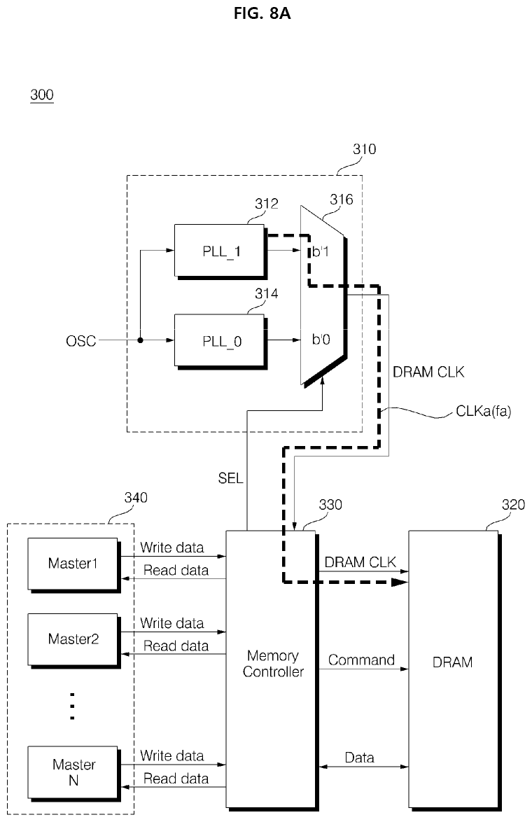

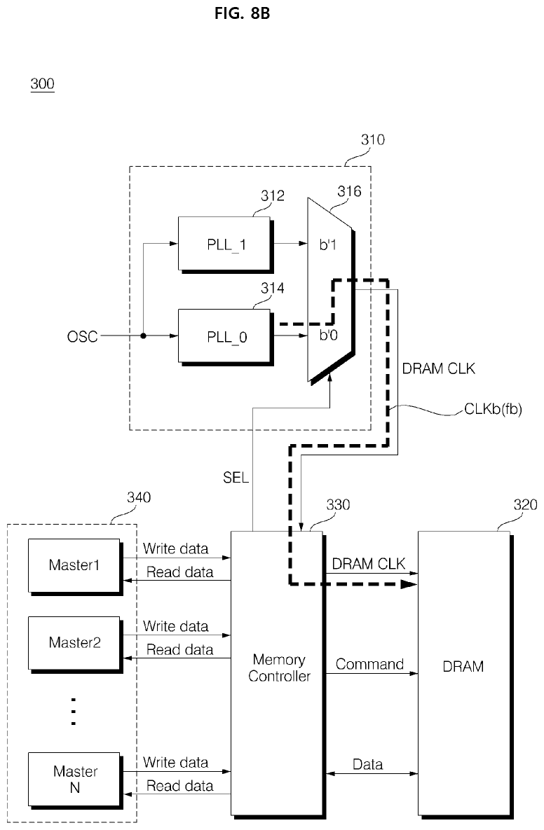

In particular, FIG. 7 is a flowchart illustrating an operation method of a memory device according to an embodiment of the present invention, and FIG. 8A to FIG. 11 are diagrams illustrating various examples of an operation method of a memory device of FIG. 7. First, referring to FIG. 7, in the memory device 300 of FIG. 3 having a dual PLL, a memory traffic examination is performed (S702).

If the examined memory traffic is in the normal range between the minimum value and the maximum value, the parameter of the second PLL 314 is set (S706). After setting the parameter of the second PLL 314, it is determined whether the phase detection is completed (S707). If so, the parameter of the memory controller 330 is set (S708).

Then, dynamic frequency scaling is started (S710). Next, after the dynamic frequency scaling, the memory access blocking is started (S715), the frequency of clock signal from the second PLL 314 is changed based on the set parameter of the second PLL 314, and the operation frequency of the memory is changed based on the changed frequency of clock signal (S740).

After changing the operation frequency of the memory 320, the memory access is restarted (S743), and the completion of the dynamic frequency scaling is checked (S746). According to the memory device 300 of the present invention of FIG. 7, the memory 320 access blocking is accomplished from step S715 to step S743.

In addition, the phase detection completion determination step S707 takes approximately 5 to 10 μs, but it is already performed before the access to the memory 320 is blocked. Accordingly, the memory access blocking period PBk from the step S715 to the step S743 takes approximately 1 to 2 μs.

Therefore, the memory access blocking period PBk can be reduced by 3 to 12 times, in comparison with the memory access blocking period PBk of FIG. 6 which takes approximately 6 to 12 μs. Accordingly, when various events of the image display apparatus are generated, the event can be performed stably, in addition to the change of the operation frequency of the memory 320

That is, according to the memory device 300 according to the embodiment of the present invention, dynamic frequency scaling for changing the frequency of clock signal of the memory 320 is performed based on the dual PLL, phase detection is performed before starting the dynamic frequency scaling, and the frequency of clock signal of the memory 320 is changed during the memory 320 access blocking according to dynamic frequency scaling. Accordingly, the memory 320 access blocking time can be reduced when the frequency of clock signal of the memory 320 is changed.

In addition, according to the memory device 300 of the embodiment of the present invention, the parameter of the second PLL 314 is set during operation of the memory 320, based on the first clock signal from the first PLL 312 of the dual PLL, and dynamic frequency scaling is performed after performing phase detection. Accordingly, the access blocking time can be reduced when the frequency of clock signal of the memory 320 is changed.

Further, according to the memory device 300 of the embodiment of the present invention, after the parameter of the second PLL 314 is set, parameter setting of the memory controller 330 is performed, and dynamic frequency scaling is performed. Accordingly, the access blocking time can be reduced when the frequency of clock signal of the memory 320 is changed.

Also, according to the memory device 300 of the embodiment of the present invention, the frequency of clock signal of the memory 320 can be changed, based on the second clock signal according to the set parameter of the second PLL 314, when the frequency of clock signal of the memory 320 is changed. Accordingly, the memory 320 access blocking time can be reduced when the frequency of clock signal of the memory 320 is changed.

In addition, according to the memory device 300 of the embodiment of the present invention, dynamic frequency scaling is performed according to the traffic of the memory 320. In particular, as the traffic of memory 320 increases, the frequency of clock signal of memory 320 increases. Accordingly, the power consumption can be varied according to the traffic of the memory 320.

Further, according to the memory device 300 of the embodiment of the present invention, the maximum frequency of clock signal of the memory 320 is not an integer multiple of the minimum frequency. Accordingly, the change into various frequencies can be achieved when the frequency of clock signal of the memory 320 is changed. In addition, according to the memory device 300 of the embodiment of the present invention, the first PLL 312 and the second PLL 314 of the dual PLL outputs a corresponding clock signal alternately to perform dynamic frequency scaling.

Next, FIG. 8A illustrates that the memory 320 operates at a first operation frequency fa, based on a first clock signal CLKa from the first PLL 312 of the dual PLL, and FIG. 8B illustrates that the memory 320 operates at a second operation frequency fb, based on a second clock signal CLKb from the second PLL 314 of the dual PLL.

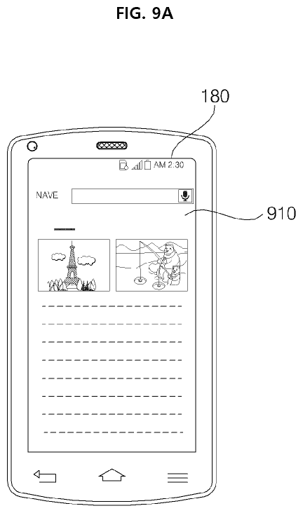

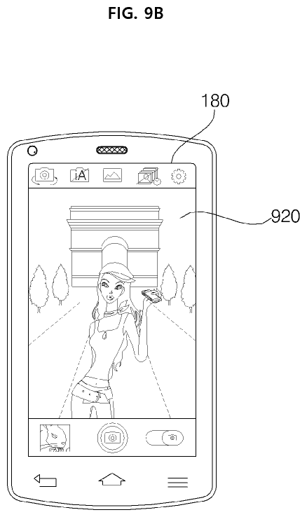

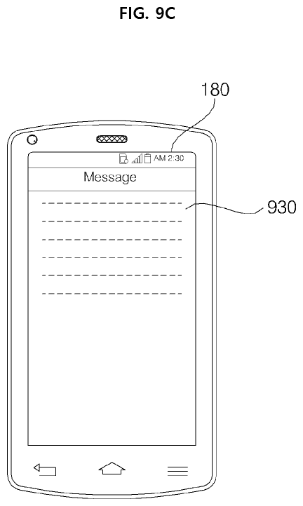

Further, FIG. 9A illustrates that an Internet screen 910 is displayed on the display 180 of the image display apparatus 100, FIG. 9B illustrates that a camera screen 920 is displayed on the display 180 of the image display apparatus 100, and FIG. 9C illustrates that a message transmission screen 930 is displayed on the display 180 of the image display apparatus 100.

The image display apparatus 100 can perform various events or applications as shown in FIGS. 9A to 9C. The controller 170 of the image display apparatus 100 can change the frequency of clock signal of the memory 320 in the memory device 300 according to an executed event.

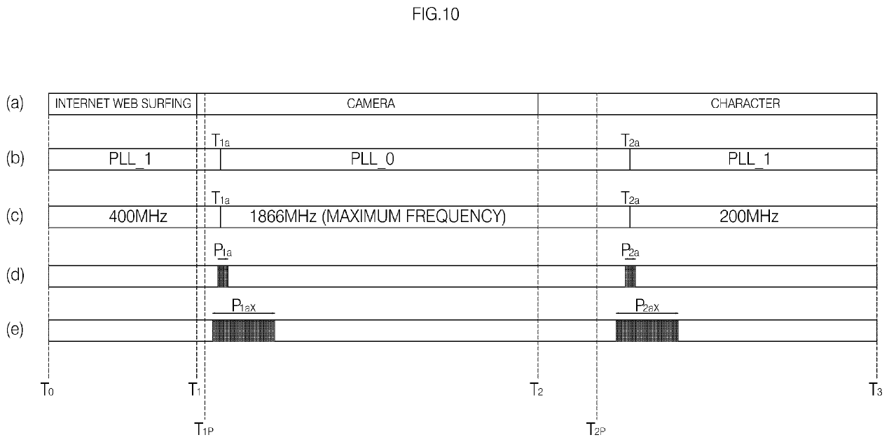

Next, FIG. 10A illustrates that the Internet screen 910 of FIG. 9A is displayed from a time point of To to a time point T1, illustrates that a camera view screen 920 of FIG. 9B is displayed from the time point T1 to a time point T2, and illustrates that a message transmission screen 930 of FIG. 9C is displayed from the time point T2 to a time point T3.

In addition, a frequency change request may occur according to the execution of camera event at a time point Tip after the time point T1, and a frequency change request may occur according to the execution of character transmission event at a time point T2p after the time point T2. In response to various event occurrences as shown in FIG. 10A, FIG. 10B illustrates that the first PLL 342 of the dual PLL in the memory device 300 operates from the time point To to a time point T1a, the second PLL 344 of the dual PLL in the memory device 300 operates from the time point T1a to a time point T2a, and the first PLL 342 of the dual PLL in the memory device 300 operates from the time point T2a to the time point T3.

Next, FIG. 10C illustrates that the memory 320 operates at an operation frequency of 400 MHz according to the operation of the first PLL 342 of the dual PLL in the memory device 300 from the time point To to the time point T1a, the memory 320 operates at an operation frequency (maximum frequency) of 1866 MHz according to the operation of the second PLL 344 of the dual PLL in the memory device 300 from the time point Tla to the time point T2a, and the memory 320 operates at an operation frequency of 200 MHz according to the operation of the first PLL 342 of the dual PLL in the memory device 300 from the time point T2a to the time point T3.

Next, FIG. 10D is a diagram illustrating a memory access blocking period during event switching according to the memory device 300 of the present invention. Specifically, the P1a period represents a memory access blocking period when a camera event is executed, and the P2a period represents a memory access blocking period when a character transmission event is executed.

FIG. 10E is a diagram illustrating a memory access blocking period during event switching according to the conventional memory device 400 having the single PLL of FIG. 4A. Specifically, the P1ax period represents a memory access blocking period when the camera event is executed, and the P2ax period represents a memory access blocking period when the character transmission event is executed.

It can be seen that the P1a period and the P2a period in FIG. 10D are significantly shorter than the P1ax period and the P2ax period in FIG. 10E. Therefore, in the present invention, there is no problem that a camera shutter response is delayed, the screen is broken, or the like, when it is switched to the camera event.

Further, in the present invention, there is no problem that a character input response is delayed, a screen is broken, or the like, when it is switched to the character transmission event. In addition, the power consumption can be reduced.

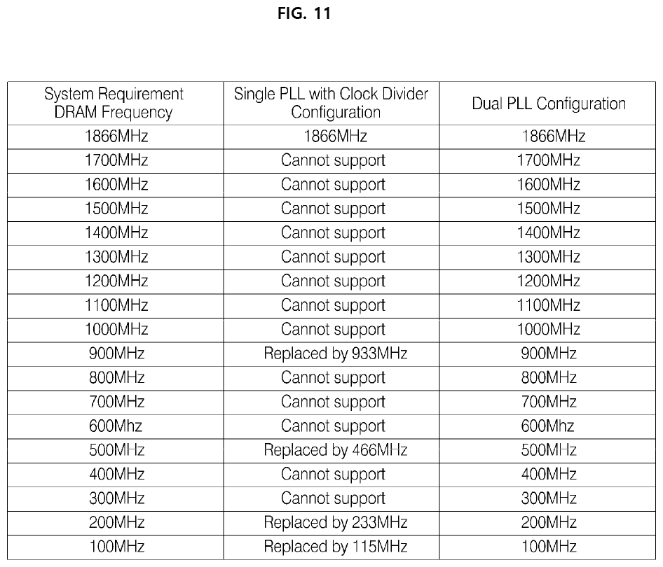

Next, FIG. 11 is a diagram illustrating the operation frequency of the conventional memory and of the memory of the present invention. Referring to the drawing, according to the conventional memory device 400 having the single PLL of FIG. 4A, when the maximum frequency of the operation frequency of the memory 320 is 1866 MHz, only 933 MHz, 466 MHz, 233 MHz, and 115 MHz, which are 1/n of 1866 MHz, are available.

However, according to the memory device 300 of the present invention having the dual PLL of FIG. 3, it can be operated at various operation frequencies from 1866 MHz, 1700 MHz to 100 MHz. Accordingly, it can be operated at an operation frequency suitable for the traffic of the memory 320. Hence, power consumption can be reduced.

As is apparent from the above description, according to an embodiment of the present invention, the memory device and the image display apparatus including the same include a memory; a clock generator configured to have a dual phase locked loop (PLL) and output a clock signal of the memory; and a memory controller configured to control the memory, wherein dynamic frequency scaling for changing a frequency of clock signal of the memory is performed based on the dual PLL, wherein phase detection is performed before the dynamic frequency scaling is started, and the frequency of clock signal of the memory is changed during blocking of access to the memory according to the performance of the dynamic frequency scaling. Accordingly, the memory access blocking period can be reduced when changing the frequency of the memory clock signal.

During operation of the memory, based on a first clock signal from a first PLL of the dual PLL, a parameter of a second PLL is set, the phase detection is performed, and then, the dynamic frequency scaling is performed. Accordingly, the memory access blocking period can be reduced when changing the frequency of the memory clock signal.

In addition, after the parameter of the second PLL is set, parameter setting of the memory controller is performed, and the dynamic frequency scaling is performed. Accordingly, the memory access blocking period can be reduced when changing the frequency of the memory clock signal.

Also, the frequency of clock signal of the memory is changed, based on a second clock signal according to the set parameter of the second PLL, when the frequency of clock signal of the memory is changed. Accordingly, the memory access blocking period can be reduced when changing the frequency of the memory clock signal.

Further, the dynamic frequency scaling is performed according to traffic of the memory. In particular, the frequency of clock signal of the memory increases as the traffic of the memory increases. Accordingly, power consumption can be varied according to traffic of the memory.

A maximum frequency of the frequency of clock signal of the memory is not an integer multiple of a minimum frequency. Accordingly, the memory access blocking period can be reduced when changing the frequency of the memory clock signal. In addition, a first PLL and a second PLL of the dual PLL alternately output a corresponding clock signal to accomplish the dynamic frequency scaling.

According to another embodiment of the present invention, the memory device and the image display apparatus including the same include a memory; a clock generator configured to have a dual phase locked loop (PLL) and output a clock signal of the memory; and a memory controller configured to control the memory, wherein dynamic frequency scaling for changing a frequency of clock signal of the memory is performed based on the dual PLL, wherein a maximum frequency of the frequency of clock signal of the memory is not an integer multiple of a minimum frequency.

In addition, a first PLL and a second PLL of the dual PLL alternately output a corresponding clock signal to accomplish the dynamic frequency scaling. Accordingly, the memory access blocking period can be reduced when changing the frequency of the memory clock signal. In addition, a second PLL is set while the memory is operating based on a first clock signal from a first PLL of the dual PLL, and the dynamic frequency scaling is performed based on a second clock signal from the second PLL. Accordingly, the memory access blocking period can be reduced when changing the frequency of the memory clock signal.

Further, a frequency of clock signal of a memory in the memory device is changed according to an event performed by the controller. Particularly, as the memory traffic of the event performed by the controller of the image display apparatus increases, the frequency of clock signal of the memory increases. Accordingly, power consumption can be varied according to an event performed by the controller of the image display apparatus.

Although the preferred embodiments of the present invention have been disclosed for illustrative purposes, those skilled in the art will appreciate that various modifications, additions and substitutions are possible, without departing from the scope and spirit of the invention as disclosed in the accompanying claims.

What is claimed is:

1. A memory device comprising:
a memory;
a clock generator including a dual phase locked loop (PLL) and outputting a clock signal of the memory; and
a memory controller configured to:
perform dynamic frequency scaling for changing a frequency of the clock signal of the memory based on the dual PLL,
wherein phase detection is performed before the dynamic frequency scaling is started, and
change the frequency of the clock signal of the memory during blocking of access to the memory according to the performance of the dynamic frequency scaling.

2. The memory device of claim 1, wherein the memory controller is further configured to:
during operation of the memory, based on a first clock signal from a first PLL of the dual PLL, set a parameter of a second PLL of the dual PLL, perform the phase detection, and then perform the dynamic frequency scaling.

3. The memory device of claim 2, wherein the memory controller is further configured to:
after the parameter of the second PLL is set, perform a parameter setting of the memory controller, and perform the dynamic frequency scaling.

4. The memory device of claim 2, wherein the frequency of clock signal of the memory is changed, based on a second clock signal according to the set parameter of the second PLL, when the frequency of clock signal of the memory is changed.

5. The memory device of claim 1, wherein the memory controller is further configured to:
when the frequency of clock signal of the memory is changed, block the access to the memory.

6. The memory device of claim 1, wherein the memory controller is further configured to perform the dynamic frequency scaling according to a traffic of the memory.

7. The memory device of claim 6, wherein the frequency of clock signal of the memory increases as the traffic of the memory increases.

8. The memory device of claim 1, wherein a maximum frequency of the frequency of clock signal of the memory is not an integer multiple of a minimum frequency.

9. The memory device of claim 1, wherein a first PLL and a second PLL of the dual PLL alternately output a corresponding clock signal to accomplish the dynamic frequency scaling.

10. A memory device comprising:
a memory;
a clock generator including a dual phase locked loop (PLL) and outputting a clock signal of the memory; and
a memory controller configured to:
perform dynamic frequency scaling for changing a frequency of the clock signal of the memory based on the dual PLL,
wherein a maximum frequency of the frequency of the clock signal of the memory is not an integer multiple of a minimum frequency.

11. The memory device of claim 10, wherein a first PLL and a second PLL of the dual PLL alternately output a corresponding clock signal to perform the dynamic frequency scaling.

12. The memory device of claim 10, wherein a second PLL is set while the memory is operating based on a first clock signal from a first PLL of the dual PLL, and the dynamic frequency scaling is performed based on a second clock signal from the second PLL.

13. The memory device of claim 12, wherein the dynamic frequency scaling is started after setting the second PLL, and a self refresh mode of the memory is performed after the start of the dynamic frequency scaling.

14. An image display apparatus comprising:
a display;
a controller; and
a memory device,
wherein the memory device comprising:
a memory;
a clock generator including a dual phase locked loop (PLL) and outputting a clock signal of the memory; and
a memory controller configured to:
perform dynamic frequency scaling for changing a frequency of the clock signal of the memory based on the dual PLL,
wherein phase detection is performed before the dynamic frequency scaling is started, and
change the frequency of clock signal of the memory during blocking of access to the memory according to the performance of the dynamic frequency scaling.

15. The image display apparatus of claim 14, wherein a frequency of clock signal of a memory in the memory device is changed according to an event performed by the controller.

16. The image display apparatus of claim 14, wherein the memory controller is further configured to:
during operation of the memory, based on a first clock signal from a first PLL of the dual PLL, set a parameter of a second PLL of the dual PLL, perform the phase detection, and then perform the dynamic frequency scaling is performed.

17. The image display apparatus of claim 16, wherein the memory controller is further configured to:
after the parameter of the second PLL is set, perform parameter setting of the memory controller, and perform the dynamic frequency scaling.

18. The image display apparatus of claim 16, wherein the frequency of clock signal of the memory is changed, based on a second clock signal according to the set parameter of the second PLL, when the frequency of clock signal of the memory is changed.

19. The image display apparatus of claim 14, wherein the memory controller is further configured to:
when the frequency of clock signal of the memory is changed, block the access to the memory.

20. The image display apparatus of claim 14, wherein the memory controller is further configured to:
perform the dynamic frequency scaling according to a traffic of the memory.
